(19) United States
(12) Patent Application Publication
(10) Pub. No.: US 2026/0223293 A1
(43) Pub. Date: Jul. 30, 2026

(54) CHIP-EMBEDDED PRINTED CIRCUIT BOARD STRUCTURE AND METHOD FOR MANUFACTURING SAME

(71) Applicant: SHANGHAI INSTITUTE OF MICROSYSTEM AND INFORMATION TECHNOLOGY, CHINESE ACADEMY OF SCIENCES, Shanghai (CN)

(72) Inventor: Kelaiti XIAO, Shanghai (CN)

(73) Assignee: SHANGHAI INSTITUTE OF MICROSYSTEM AND INFORMATION TECHNOLOGY, CHINESE ACADEMY OF SCIENCES, Shanghai (CN)

(21) Appl. No.: 19/142,979

(22) PCT Filed: May 21, 2024
(86) PCT No.: PCT/CN2024/094332

§ 371 Date: Jun. 25, 2025

(30) Foreign Application Priority Data
May 29, 2023 (CN) 202310616777X

(51) Int. Cl. H05K 1/185; H05K 1/11; H05K 3/34

(52) U.S. Cl. CPC H05K 1/185; H05K 1/115; H05K 3/34; H05K 2201/09545; H05K 2201/09563

(57) ABSTRACT

The present disclosure provides a chip-embedded printed circuit board structure and a method for manufacturing the same. The structure includes: a conductive substrate; a conductive metal layer and a chip bonded to a same surface of the conductive substrate with their upper surfaces being flush; an insulating material layer; a redistribution layer; and plated through holes. The conductive metal layer and the chip are bonded to the surface of the conductive substrate. Furthermore, the provision of a conductive metal layer that is flush with the surface of a chip prevents defects such as voids during the lamination of the insulating layer. Additionally, since the chip and the conductive metal layer are flush, the formed through holes have a uniform depth. Finally, the provision of the conductive metal layer effectively reduces the length of the plated through holes and shortens the circuit length.

### FIELD OF TECHNOLOGY

The present disclosure relates to the technical field of printed circuit boards, and in particular to a chip-embedded printed circuit board structure and a method for manufacturing the same.

### BACKGROUND

In recent years, portable mobile electronic products, such as cell phones, and notebook computers, have been developing towards higher speed, multifunctionality and miniaturization. High-frequency and high-speed signal transmission also requires increasingly shorter interconnection distances between electronic components. As a result, traditional electronic packaging and assembly methods can no longer meet these requirements. Embedding active or passive devices, especially power chips, in printed wiring boards is a packaging approach that is expected to solve these problems, and this technology has attracted extensive research and development in recent years.

Research on power chip embedding technologies began with low-power chips. For example, in 2010, Texas Instruments developed the MicroSiP™ technology, in which a low-power DC-DC converter is formed using an organic substrate in which bare MOSFET dies are embedded, together with surface-mounted components. Similar technologies include DrBlade™ by Infineon and SESUB by TDK. In recent years, stimulated by the development of compound semiconductors and driven by the demand for rapid growth of electric vehicles, researchers have begun to conduct research on the embedding of high-power chips into printed circuit boards, with device voltages reaching up to 1200 V and power up to 100 KW. Embedded-type printed circuit boards are well suited for high-switching-frequency wide-bandgap semiconductor chips, such as SiC MOSFETs and GaN HEMTs, as they can significantly reduce the circuit length and thereby lower parasitic inductance. Currently, there are two main types of power device embedding technologies or research.

A first type is the chip-on-substrate technology developed by Fraunhofer IZM in 1999. Later, Munding and others developed an embedding process using a lead frame as a substrate based on this. The first step of the process is to attach a chip 20 to a substrate 21, as shown in FIG. 7. Subsequently, a prepreg 22 is pressed, as shown in FIG. 8. Then, holes 23 are drilled to expose pads 25 on the chip, as shown in FIGS. 7 and 9. Finally, wiring 24 is formed by electroplating and etching processes, as shown in FIG. 10. This method successfully achieves power chip embedding. However, it also presents significant drawbacks. First, a height difference between the chip and the substrate may lead to voids or other defects during subsequent lamination, requiring the prepreg to be cut and the process to be precisely controlled. Second, the height difference between the chip and the substrate results in through holes of two different depths, which creates difficulty for subsequent electroplating. A second type is the chip mounting technology within a cavity of a substrate. Its structure and process flow are shown in FIGS. 11 and 12. FIG. 11 illustrates a face-up chip, and FIG. 12 illustrates a flip-chip. First, a substrate 21 or a frame is etched to form a cavity 26 for accommodating a chip 20. Then, the chip 20 is bonded to the substrate 21. Subsequently, a PCB process is performed to complete the entire process. Drawbacks of this structure are also apparent. First, the formation of the deep cavity increases the cost, and it is difficult to control the depth and width of the cavity. Second, this structure does not allow a chip bonding material to be applied by printing, and instead, only a dispensing method can be used to apply solder, silver paste, and the like, which significantly increases the difficulty and cost of the mounting process.

### SUMMARY

The present disclosure provides a chip-embedded printed circuit board structure and a method for manufacturing the same, thus solving the problems in the related art described above.

The chip-embedded printed circuit board structure includes:
a conductive substrate including a first surface and a second surface opposite to the first surface;
a conductive metal layer and a chip bonded to a same surface of the conductive substrate, wherein upper surfaces of the conductive metal layer and the chip are flush with each other;
an insulating material layer, disposed at least on the first surface of the conductive substrate where the conductive metal layer and the chip are located, and encapsulating the conductive metal layer and the chip;
a redistribution layer, disposed at least on one surface of the insulating material layer that encapsulates the conductive metal layer and the chip; and
plated through holes, including through holes and a metal filler layer filling the through holes, extending inward from a surface of the redistribution layer to connect to the conductive metal layer and the chip, respectively, so as to electrically connect the redistribution layer to the conductive metal layer and the chip.

Optionally, the chip includes a power chip.

Optionally, the conductive substrate is a metal substrate or a substrate formed by an insulating layer covered with a metal layer.

Further, the conductive substrate is a copper metal substrate or a copper-clad ceramic substrate.

Optionally, the insulating material layer is also disposed on the second surface of the substrate, and the redistribution layer is also disposed on a surface of the insulating material layer.

Optionally, a material of the conductive metal layer includes copper.

Optionally, the conductive metal layer and the chip are soldered onto the conductive substrate by solder.

The present disclosure further provides a method for manufacturing a chip-embedded printed circuit board structure, the method includes:
providing a conductive substrate, wherein the conductive substrate includes a first surface and a second surface opposite to the first surface;
bonding a conductive metal layer and a chip to a same surface of the conductive substrate, wherein upper surfaces of the conductive metal layer and the chip are flush with each other after the bonding;
forming an insulating material layer and a redistribution material layer successively on the first surface of the conductive substrate where the conductive metal layer and the chip are located;
etching from a surface of the redistribution material layer to form through holes connecting to the surface of the conductive metal layer and the surface of the chip; and
filling the through holes with a metal filler layer to form plated through holes, and patterning the redistribution material layer to form a redistribution layer.

Optionally, the insulating material layer and the redistribution material layer are also successively formed on the second surface of the conductive substrate.

Further, the conductive metal layer and the chip are soldered onto the same surface of the conductive substrate by solder; the insulating material layer is formed by pressing an insulating partially cured dielectric film to fill voids; the through holes are formed by laser drilling; and the through holes are filled by an electroplating process.

As described above, according to the chip-embedded printed circuit board structure and the method for manufacturing the same in the present disclosure, the conductive metal layer and the chip are bonded to the surface of the conductive substrate. This eliminates the need to fabricate a deep cavity structure for bonding the chip, thereby avoiding increased manufacturing costs and the difficulty associated with deep cavity preparation, while also reducing the complexity of the chip mounting process. Furthermore, the provision of a conductive metal layer that is flush with the surface of a chip prevents defects such as voids during the lamination of the insulating layer. Additionally, since the chip and the conductive metal layer are flush, the formed through holes have a uniform depth, effectively reducing the difficulty of etching the through holes and the subsequent hole-filling process. Finally, the provision of the conductive metal layer effectively reduces the length of the plated through holes, shortening the circuit length and thus lowering parasitic inductance and improving device performance.

### BRIEF DESCRIPTION OF THE DRAWINGS

FIG. 1 shows a schematic diagram of a cross-sectional structure of a conductive substrate provided in a method for manufacturing a chip-embedded printed circuit board structure according to Embodiment 1 of the present disclosure.

FIG. 2 shows a schematic diagram of a cross-sectional structure of printing solder in the method for manufacturing the chip-embedded printed circuit board structure according to Embodiment 1 of the present disclosure.

FIG. 3 shows a schematic diagram of a cross-sectional structure of bonding a conductive metal layer and a chip in the method for manufacturing the chip-embedded printed circuit board structure according to Embodiment 1 of the present disclosure.

FIG. 4 shows a schematic diagram of a cross-sectional structure of forming an insulating material layer and a redistribution material layer in the method for manufacturing a chip-embedded printed circuit board structure according to Embodiment 1 of the present disclosure.

FIG. 5 shows a schematic diagram of a cross-sectional structure of forming through holes in the method for manufacturing a chip-embedded printed circuit board structure according to Embodiment 1 of the present disclosure.

FIG. 6 shows a schematic diagram of a cross-sectional structure of forming a metal filler layer and a redistribution layer to form a chip-embedded printed circuit board structure in the method for manufacturing a chip-embedded printed circuit board structure according to Embodiment 1 of the present disclosure.

FIGS. 7 to 10 show schematic diagrams of cross-sectional structures of steps in the manufacturing method for an exemplary chip-embedded printed circuit board structure.

FIG. 11 shows a schematic diagram of a cross-sectional structure of another exemplary chip-embedded printed circuit board structure.

FIG. 12 shows a schematic diagram of a cross-sectional structure of yet another exemplary chip-embedded printed circuit board structure.

Reference Numerals

| | |
|---|---|
| 10 | Conductive substrate |
| 100 | Solder |
| 101 | Isolation hole |
| 11 | Conductive metal layer |
| 12 | Chip |
| 13 | Insulating material layer |
| 14 | Redistribution material layer |
| 15 | Through hole |
| 16 | Metal filler layer |
| 17 | Redistribution layer |
| 20 | Chip |
| 21 | Substrate |
| 22 | Prepreg |
| 23 | Hole |
| 24 | Wiring |
| 25 | Pad |
| 26 | Cavity |

### DETAILED DESCRIPTION

Implementations of the present disclosure will be described below with specific examples, and other advantages and effects of the present disclosure will be readily apparent to those skilled in the art from the disclosure in the specification. The present disclosure may be carried out or applied by other different specific implementations, and various modifications or changes may also be made to the details of the specification based on different ideas and applications without departing from the spirit of the present disclosure.

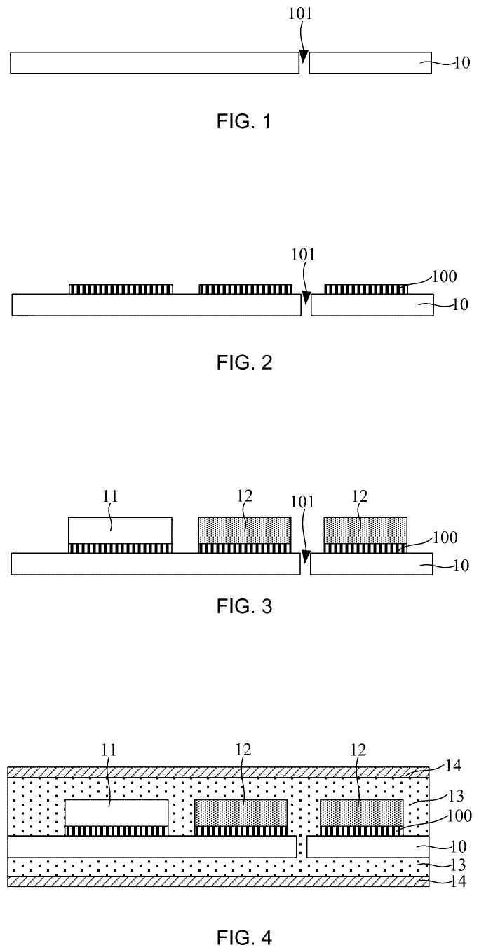

Please refer to FIGS. 1 to 6. It is to be noted that drawings provided in the embodiments only schematically illustrate the basic idea of the present disclosure, so the drawings only show components related to the present disclosure, and are not drawn according to the numbers, shapes and sizes of the components in actual implementations; the forms, numbers and proportions of the components in actual implementations may represent an arbitrary variant; and the layout of the components may be more complex.

### Embodiment 1

This embodiment provides a method for manufacturing a chip-embedded printed circuit board structure. The method includes the following steps:
S1: providing a conductive substrate including a first surface and a second surface opposite to the first surface;
S2: bonding a conductive metal layer and a chip to a same surface of the conductive substrate, wherein upper surfaces of the conductive metal layer and the chip are flush with each other after the bonding;
S3: forming an insulating material layer and a redistribution material layer successively on the first surface of the conductive substrate where the conductive metal layer and the chip are located;
S4: etching from a surface of the redistribution material layer to form through holes connecting to the surface of the conductive metal layer and the surface of the chip; and
S5: filling the through holes with a metal filler layer to form plated through holes, and patterning the redistribution material layer to form a redistribution layer.

In the method for manufacturing the chip-embedded printed circuit board structure in this embodiment, the conductive metal layer and the chip are bonded to the surface of the conductive substrate. This eliminates the need to fabricate a deep cavity structure for bonding the chip, thereby avoiding increased manufacturing costs and the difficulty associated with deep cavity preparation, while also reducing the complexity of the chip mounting process. Furthermore, the provision of a conductive metal layer that is flush with the surface of a chip prevents defects such as voids during the lamination of the insulating layer. Additionally, since the chip and the conductive metal layer are flush, the formed through holes have a uniform depth, effectively reducing the difficulty of etching the through holes and the subsequent hole-filling process. Finally, the provision of the conductive metal layer effectively reduces the length of the plated through holes, shortening the circuit length and thus lowering parasitic inductance and improving device performance. The method for manufacturing the chip-embedded printed circuit board structure in this embodiment is described in detail below in conjunction with the specific drawings.

As shown in FIG. 1, step S1 is performed first: a conductive substrate 10 is provided, and the conductive substrate 10 includes a first surface and a second surface opposite to the first surface.

Here, it is to be noted that the thickness of the conductive substrate 10 is selected according to actual needs. Additionally, the conductive substrate 10 may be a metal substrate of a pure metal material, or may be a substrate formed by an insulating layer covered with a metal layer. For example, the conductive substrate 10 may be a commonly used copper metal substrate or copper-clad ceramic substrate. Metals other than copper can also be selected; any substrate material suitable for manufacturing printed circuit boards can be used.

As an example, silver plating may also be performed in an area on a surface of the conductive substrate 10 where subsequent bonding of a conductive metal layer and a chip is required, to improve the reliability of subsequent soldering of the conductive metal layer and the chip on the conductive substrate 10.

According to actual needs, a plurality of chips may need to be bonded to the conductive substrate 10, so an isolation hole 101 running through the conductive substrate 10 is formed in the conductive substrate 10, and subsequently the isolation hole 101 is filled with an insulating material to improve electrical insulation between the chips.

As shown in FIG. 3, then step S2 is performed: a conductive metal layer 11 and a chip 12 are bonded to a same surface of the conductive substrate 10, wherein upper surfaces of the conductive metal layer 11 and the chip 12 are flush with each other after the bonding.

Here, it is to be noted that the numbers of conductive metal layer 11 and the chip 12 bonded to the conductive substrate 10 are selected according to actual needs. For example, one conductive metal layer 11 and two chips 12 are provided as shown in FIG. 3.

As shown in FIG. 2, as a preferred example, solder 100 may be printed in an area on the surface of the conductive substrate 10 where the conductive metal layer 11 and the chip 12 need to be bonded. The solder 100 may be conductive or non-conductive solder, such as silver-containing solder, tin-containing solder, silver-containing tin solder, or gold-containing tin solder, etc. Then, the conductive metal layer 11 and the chip 12 are placed on the solder 100. Finally, soldering is performed so that the conductive metal layer 11 and the chip 12 are bonded to the conductive substrate 10. As described above, if silver plating is performed in the area on the surface of the conductive substrate 10 where the conductive metal layer and the chip are bonded, using the solder to solder the conductive metal layer 11 and the chip 12 can effectively improve the reliability of the soldering.

Since a bonding material layer is very thin and the bonding is uniform, the thickness of the conductive metal layer 11 is generally set to be the same as the that of the chip 12, such that the upper surfaces of the conductive metal layer 11 and the chip 12 can be flush with each other after the bonding.

As an example, the conductive metal layer 11 is made of any metal material suitable for achieving an electrical connection, such as copper. The chip 12 may be any chip intended to be embedded in a printed circuit board, such as a power chip.

As shown in FIG. 4, subsequently step S3 is performed: an insulating material layer 13 and a redistribution material layer 14 are successively formed on the first surface of the conductive substrate 10 where the conductive metal layer 11 and the chip 12 are located.

As shown in FIG. 4, as an example, according to actual needs, the insulating material layer 13 and the redistribution material layer 14 may also be formed successively on the other surface of the conductive substrate 10, which means that both surfaces of the conductive substrate 10 are formed with the insulating material layer 13 and the redistribution material layer 14.

As an example, a method for forming the insulating material layer 13 may be implemented by a PCB process in which a partially cured dielectric film is laminated and then pressed for filling. The partially cured dielectric film may be a partially cured dielectric film with flowability. During pressing for filling, the flowable partially cured dielectric film fills all voids, thereby forming the insulating material layer 13 without voids. Alternatively, the partially cured dielectric film may be a partially cured dielectric film without flowability. In this case, the partially cured dielectric film is cut according to parameters such as the shapes and sizes of the conductive metal layer 11 and the chip 12, and is then pressed for filling, thereby forming the insulating material layer 13 without voids.

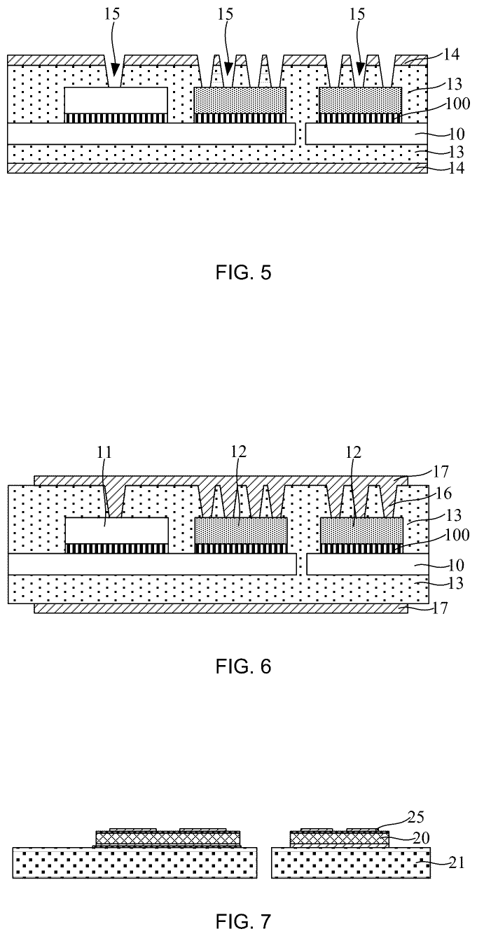

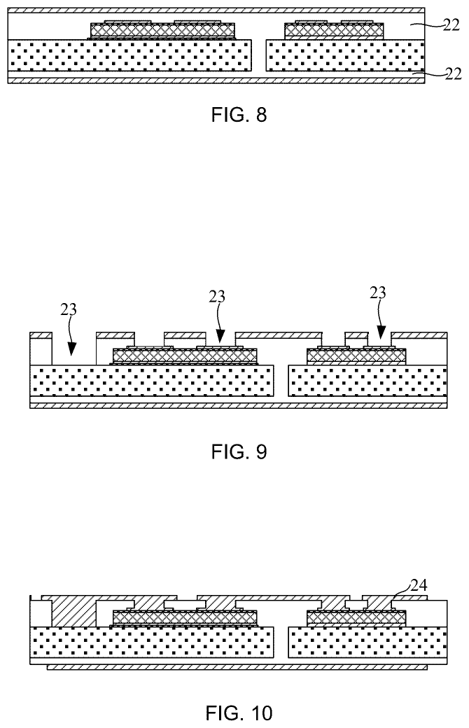

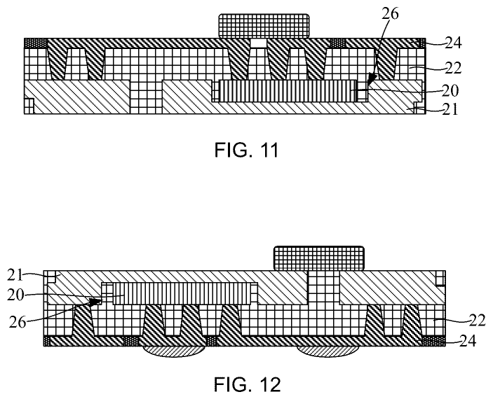

As shown in FIG. 5, subsequently, step S4 is performed: through holes 15 connecting to the surface of the conductive metal layer 11 and the surface of the chip 12 are formed by etching from a surface of the redistribution material layer 14.

Any suitable dry etching method may be used to form the through holes 15. Preferably, the through holes 15 are formed by laser drilling, which offers high efficiency, produces hole surfaces with minimal burrs, and allows for easy control, thereby improving drilling quality.

Since the upper surfaces of the conductive metal layer 11 and the chip 12 are flush with each other, the through holes 15 formed by etching have uniform depths, which greatly reduces the difficulty of etching the through holes and improves the etching efficiency.

It is to be noted here that in the case where both surfaces of the conductive substrate 10 are formed with the insulating material layer 13 and the redistribution material layer 14, through holes may also be formed in the insulating material layer 13 and the redistribution material layer 14 on both surfaces of the conductive substrate 10 according to actual needs, to achieve interconnection of the entire circuit. This is common knowledge in the art.

As shown in FIG. 6, finally step S5 is performed: the through holes 15 are filled with a metal filler layer 16 to form plated through holes, and the redistribution material layer 14 is patterned to form a redistribution layer 17.

As an example, the through holes 15 are filled by an electroplating process to form plated through holes.

The shape of the redistribution layer 17 is set according to actual needs.

Due to the use of the conductive metal layer flush with the chip, the lengths of the plated through holes are greatly reduced, thereby shortening the circuit length, effectively reducing parasitic inductance, and improving device performance.

The metal filler layer 16 may be made of any suitable electrical connection metal material, such as copper material.

### Embodiment 2

This embodiment provides a chip-embedded printed circuit board structure. The chip-embedded printed circuit board structure may be manufactured by using the method in Embodiment 1 described above. For beneficial effects that can be achieved, reference may be made to Embodiment 1. As shown in FIG. 6, the chip-embedded printed circuit board structure includes:
a conductive substrate 10 including a first surface and a second surface opposite to the first surface;
a conductive metal layer 11 and a chip 12 bonded to a same surface of the conductive substrate 10, wherein upper surfaces of the conductive metal layer 11 and the chip 12 are flush with each other;
an insulating material layer 13 disposed at least on the first surface of the conductive substrate 10 where the conductive metal layer 11 and the chip 12 are located, and encapsulating the conductive metal layer 11 and the chip 12;
a redistribution layer 17 disposed at least on one surface of the insulating material layer 13 that encapsulates the conductive metal layer 11 and the chip 12; and
plated through holes including through holes 15 and a metal filler layer 16 filling the through holes 15, extending inward from a surface of the redistribution layer 17 to connect to the conductive metal layer 11 and the chip 12, respectively, so as to electrically connect the redistribution layer 17 to the conductive metal layer 11 and the chip 12.

Here, it is to be noted that the thickness of the conductive substrate 10 is selected according to actual needs. Additionally, the conductive substrate 10 may be a metal substrate of a pure metal material, or may be a substrate formed by an insulating layer covered with a metal layer. For example, the conductive substrate 10 may be a commonly used copper metal substrate or copper-clad ceramic substrate. Metals other than copper can also be selected; any substrate material suitable for manufacturing printed circuit boards can be used.

As an example, silver plating may also be performed in a region of the surface of the conductive substrate 10 where the conductive metal layer and the chip are bonded, to improve the soldering reliability of the conductive metal layer and the chip on the conductive substrate 10.

According to actual needs, a plurality of chips may need to be bonded to the conductive substrate 10. Therefore, isolation holes 101 passing through the conductive substrate 10 are provided on the conductive substrate 10, and the isolation holes 101 are filled with an insulating material to improve electrical insulation between the chips.

As an example, the conductive metal layer 11 is made of any metal material suitable for achieving an electrical connection, such as copper. The chip 12 may be any chip intended to be embedded in a printed circuit board, such as a power chip.

As shown in FIG. 6, as an example, the insulating material layer 13 and the redistribution layer 17 may also be formed on the second surface of the conductive substrate 10 according to actual needs, which means that both surfaces of the conductive substrate 10 are formed with the insulating material layer 13 and the redistribution material layer 17.

The metal filler layer 16 may be made of any suitable electrical connection metal material, such as a copper material.

As an example, the conductive metal layer 11 and the chip 12 are soldered to the conductive substrate 10 by solder 100.

In summary, according to the chip-embedded printed circuit board structure and the method for manufacturing the same provided in the present disclosure, the conductive metal layer and the chip are bonded to the surface of the conductive substrate. This eliminates the need to fabricate a deep cavity structure for bonding the chip, thereby avoiding increased manufacturing costs and the difficulty associated with deep cavity preparation, while also reducing the complexity of the chip mounting process. Furthermore, the provision of a conductive metal layer that is flush with the surface of a chip prevents defects such as voids during the lamination of the insulating layer. Additionally, since the chip and the conductive metal layer are flush, the formed through holes have a uniform depth, effectively reducing the difficulty of etching the through holes and the subsequent hole-filling process. Finally, the provision of the conductive metal layer effectively reduces the length of the plated through holes, shortening the circuit length and thus lowering parasitic inductance and improving device performance. Therefore, the present disclosure effectively overcomes various shortcomings of the related art and has a high value for industrial use.

The above embodiments are merely illustrative of the principles of the present disclosure and effects thereof, and are not intended to limit the present disclosure. Any person skilled in the art can modify or change the above embodiments without departing from the spirit and scope of the present disclosure. Therefore, all equivalent modifications or changes made by those skilled in the art without departing from the spirit and technical ideas disclosed in the present disclosure are still encompassed within the scope of the claims of the present disclosure.

1. A chip-embedded printed circuit board structure, wherein the chip-embedded printed circuit board structure comprises:
a conductive substrate, wherein the conductive substrate comprises a first surface and a second surface opposite to the first surface;
a conductive metal layer and a chip bonded to a same surface of the conductive substrate, wherein upper surfaces of the conductive metal layer and the chip are flush with each other;
an insulating material layer, wherein the insulating material layer is disposed at least on the first surface of the conductive substrate where the conductive metal layer and the chip are located, and encapsulating the conductive metal layer and the chip;
a redistribution layer, wherein the redistribution layer is disposed at least on one surface of the insulating material layer that encapsulates the conductive metal layer and the chip; and
plated through holes, wherein the plated through holes comprises through holes and a metal filler layer filling the through holes, extending inward from a surface of the redistribution layer to connect to the conductive metal layer and the chip, respectively, so as to electrically connect the redistribution layer to the conductive metal layer and the chip.

2. The chip-embedded printed circuit board structure according to claim 1, wherein the chip comprises a power chip.

3. The chip-embedded printed circuit board structure according to claim 1, wherein the conductive substrate is a metal substrate or a substrate formed by an insulating layer covered with a metal layer.

4. The chip-embedded printed circuit board structure according to claim 3, wherein the conductive substrate is a copper metal substrate or a copper-clad ceramic substrate.

5. The chip-embedded printed circuit board structure according to claim 1, wherein the insulating material layer is also disposed on the second surface of the substrate, and the redistribution layer is also disposed on a surface of the insulating material layer.

6. The chip-embedded printed circuit board structure according to claim 1, wherein a material of the conductive metal layer comprises copper.

7. The chip-embedded printed circuit board structure according to claim 1, wherein the conductive metal layer and the chip are soldered onto the conductive substrate by solder.

8. A method for manufacturing a chip-embedded printed circuit board structure, wherein the method comprises:
providing a conductive substrate, wherein the conductive substrate comprises a first surface and a second surface opposite to the first surface;
bonding a conductive metal layer and a chip to a same surface of the conductive substrate, wherein upper surfaces of the conductive metal layer and the chip are flush with each other after the bonding;
forming an insulating material layer and a redistribution material layer successively on the first surface of the conductive substrate where the conductive metal layer and the chip are located;
etching from a surface of the redistribution material layer to form through holes connecting to the surface of the conductive metal layer and the surface of the chip; and
filling the through holes with a metal filler layer to form plated through holes, and patterning the redistribution material layer to form a redistribution layer.

9. The method for manufacturing the chip-embedded printed circuit board structure according to claim 8, wherein the insulating material layer and the redistribution material layer are also successively formed on the second surface of the conductive substrate.

10. The method for manufacturing the chip-embedded printed circuit board structure according to claim 8- or 9, wherein the conductive metal layer and the chip are soldered onto the same surface of the conductive substrate by solder; the insulating material layer is formed by pressing an insulating partially cured dielectric film to fill voids; the through holes are formed by laser drilling; and the through holes are filled by an electroplating process.
